(19) United States
(12) Patent Application Publication
(10) Pub. No.: US 2010/0175753 A1
(43) Pub. Date: Jul. 15, 2010

(54) SOLAR CELL MODULE

(75) Inventors: Jun MAEDA, Hagagun (JP); Takeshi Sakazaki, Hagagun (JP)

Correspondence Address: ARENT FOX LLP, 1050 CONNECTICUT AVENUE, N.W., SUITE 400, WASHINGTON, DC, 20036, US

(73) Assignee: HONDA MOTOR CO., LTD., Tokyo (JP)

(21) Appl. No.: 12/632,567

(22) Filed: Dec. 7, 2009

(30) Foreign Application Priority Data
Jan. 13, 2009 (JP) 2009-004579

(51) Int. Cl. H01L 31/00

(52) U.S. Cl. 136/256

(57) ABSTRACT

The present invention provides a solar cell module including: a solar cell element; a wiring which is connected to the solar cell element; a cover member which is disposed around the solar cell element; a protective resin which seals a space between the solar cell element and the cover member; a hole portion which is formed to the cover member, the wiring being ejected to an external portion via the hole portion; a terminal portion which is provided at an external portion of the cover member, the wiring being connected to the terminal portion; and an adsorbent which is provided on a surface of the wiring and absorbs water.

### BACKGROUND OF THE INVENTION

1. Field of the Invention

The present invention relates to a solar cell module in which a wiring from a solar cell element is connected to a terminal portion provided to an external portion of a cover member. In particular, it relates to improvement in a technique for prevention of water intrusion to an internal portion of the solar cell module through the wiring.

2. Description of Related Art

Durability to various environmental conditions (humidity, weather, and the like) is required for solar cells which are used outdoors. In order to supply this requirement, in a solar cell, plural solar cell elements are disposed in a space formed by a cover member, and the space is sealed by a protective material.

Specifically, first, a protective resin sheet of EVA (Ethylene-Vinyl Acetate) or the like, plural solar cell elements, a protective resin sheet, and a rear surface side cover member (back sheet or the like) are disposed in turn on a surface side cover member (transparent substrate or the like). In this case, surfaces (electric generation surface) of the solar cell elements face the surface side cover member, and rear surfaces of the solar cell elements face the rear surface side cover member. The solar cell elements proximate to each other are connected to each other by internal wiring. Output wiring, which is connected to corner portions of the solar cell elements, is disposed on the rear surfaces of the solar cell elements, and the output wiring is ejected to the external portion via a hole portion formed on the rear surface side cover member.

Next, the overall of the component members are integrally formed by heating and pressurizing under a reduced pressure by using a lamination apparatus. Thus, a space formed by the cover member is sealed by a protective resin of the protective resin sheet. Next, a terminal portion is provided at the external portion of the hole portion of the rear surface side cover member, and the output wiring is ejected to the external portion via an internal portion of the terminal portion. The internal portion of the terminal portion is sealed by a seal material, and is closed by a cap portion. A material having a waterproof property, a moisture-proof property, and an insulation property is desirably used as the seal material. A silicon material, which has a relatively high water repellent ratio, is superior in waterproof property and is advantageous to a mass production (material cost and fast curing), is used.

However, in the solar cell module having the above construction, the output wiring may be movable within a predetermined range due to flexibility thereof. Due to this, a gap between the output wiring and the seal material in the terminal portion may be easily formed at a hole of the terminal portion, at which the output wiring is ejected to the external portion. Thus, water may arrive at the hole portion of the rear surface side cover member through the output wiring. Water may arrive at the hole portion of the rear surface side cover member through a gap between the rear surface side cover member and the terminal portion. Since the silicon material having the above advantages is inferior to materials (urethane, epoxy resin, and the like) in water repellent ratio, water, which intrudes through a gap between the cap portion and a main body portion of the terminal portion, may not be absorbed by the silicon material and may arrive at the hole portion of the rear surface side cover member. In this case, materials (urethane, epoxy resin, and the like) may be used as the seal member, but these materials are expensive and high viscosity materials, and these materials sufficiently do not enter the internal portion of the terminal portion. Due to this, bad sealing occurs, so that the problem of water intruding through the output wiring may be serious.

The output wiring is ejected from the hole portion of the rear surface side cover member which is sealed by the protective resin, a gap may be easily formed between the output wiring and the protective resin due to the flexibility of the output wiring, and it is difficult that the protective resin enter a region proximate to the output wiring on the rear surfaces of the solar cell elements. Due to this, water which arrives at the hole portion of the rear surface side cover member by the above reasons may intrude into the internal portion of the solar cell module, and water may arrive to the surfaces (electric generation surfaces) of the solar cell elements. As a result, short circuit may occur, and the reliability may be deteriorated.

In order to prevent the formation of the gaps around the wiring, a bond or an adhesive may be coated onto the output wiring as disclosed in Japanese Unexamined Patent Application Publication No. 2006-060028. However, since interface void exist on an adhesive interface between the solar cell elements and the output wiring, water intruding from the terminal portion may easily arrive to the surfaces (electric generation surfaces) of the solar cell module through the interface gap along the output wiring. As disclosed in Japanese Unexamined Patent Application Publication No. 2000-332284, a transparent adhesive and a moistureproof material may be provided to the hole portion of the rear surface side cover member. However, in this case, mass production may be decreased, and the number of parts may increase, so that production cost may increase.

### SUMMARY OF THE INVENTION

An object of the present invention is to provide a solar cell module that can prevent water intrusion, which occurs from a hole portion of cover member through wiring, by using a simple construction, and that thereby can prevent the deterioration of the reliability due to short circuit without decrease in mass production, increase in the number of parts, and increase in production cost.

According to one aspect of the present invention, a solar cell module includes: a solar cell element; a wiring which is connected to the solar cell element; a cover member which is disposed around the solar cell element; a protective resin which seals a space between the solar cell element and the cover member; a hole portion which is formed to the cover member, the wiring being ejected to an external portion via the hole portion; a terminal portion which is provided at an external portion of the cover member, the wiring being connected to the terminal portion; and an adsorbent which is provided on a surface of the wiring and absorbs water.

In the solar cell module of the present invention, even when water arrive at the hole portion of the cover member (for example, rear surface side cover member) through a gap between the rear surface side cover member and the terminal portion, through a gap between a cap portion and a main body portion of the terminal portion, and the like, since the adsorbent absorbing water is provided on the surface of the wiring ejected to the external portion via the hole portion of the rear surface side cover member, the water arriving at the hole portion of the rear surface side cover member is absorbed by the adsorbent provided on the surface of the wiring.

Therefore, even when a gap is formed between the wiring and surrounding members on a surface side (for example, a rear surface side) of the solar cell module, intrusion of water from the hole portion of the cover member through the wiring can be prevented. As a result, deterioration of reliability due to short circuit can be prevented. Since this effect can be obtained in a simple structure that the adsorbent is provided on the surface of the wiring, improvement of mass production, reduction of the number of parts, and reduction of production cost can be realized.

The solar cell module of the present invention can use various constructions. According to one preferred embodiment of the present invention, the adsorbent of the wiring has a horizontal direction thickness parallel to a surface direction of the solar cell element, and has a vertical direction thickness perpendicular to the surface direction of the solar cell element, and the horizontal direction thickness is thicker than the vertical direction thickness. When the vertical direction thickness of the wiring is thicker, the protective resin may insufficiently enter corner portions formed between the wiring and the solar cell element, and various problems of gas bubble and the like may occur. However, in the above embodiment of the present invention, since the amount of water absorbed by the adsorbent can be larger without making the thickness of the wiring thicker, the above problems can be prevented.

According to another preferred embodiment of the present invention, the adsorbent of the wiring is a film including a material that absorbs and desorbs water, and the adsorbent adheres to the surface of the wiring. In this embodiment, the water absorbed in the wiring can be desorbed by heat, pressure, or the like, the durability of the solar cell module can be improved. According to another preferred embodiment of the present invention, the terminal portion is sealed by a silicon material. The silicon material may be superior in heat resistance, durability, weather resistance, ultraviolet light resistance, water resistance, or the like, and the silicon material may be inexpensive. Since the silicon material is not a high viscosity material, sealing of the internal portion of the terminal portion can be good.

According to the present invention, even when a gap is formed between the wiring and surrounding members on the rear surface side of the solar cell module, intrusion of water from the hole portion of the rear surface side cover member through the wiring can be prevented. As a result, deterioration of reliability due to short circuit can be prevented, and another effect can be obtained.

### BRIEF DESCRIPTION OF THE DRAWINGS

FIG. 1 is a sectional side view showing a schematic construction of a solar cell module of one embodiment according to the present invention.

FIG. 2 is a plain view showing the solar cell module in FIG. 1 which is seen from a rear surface side (lower side in FIG. 1).

FIG. 3 is a sectional side view showing a portion of the solar cell module in FIG. 1 and showing one desirable embodiment of an output wiring.

FIG. 4 is a sectional side view showing another desirable embodiment of an output wiring in FIG. 1.

### DESCRIPTION OF THE PREFERRED EMBODIMENTS

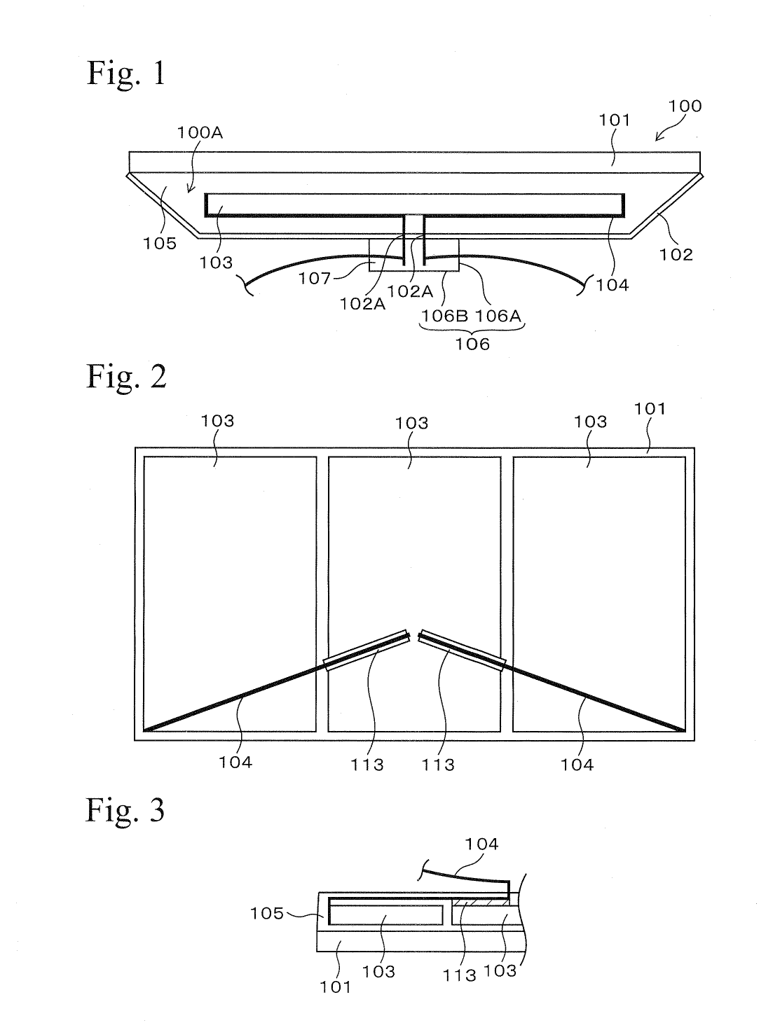

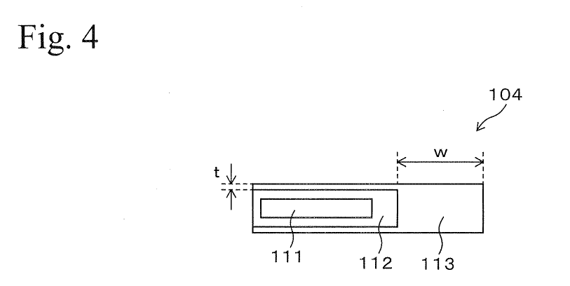

One embodiment of the present invention will be described hereinafter with reference to Figures. FIG. 1 is a sectional side view showing a schematic construction of a solar cell module 100 of one embodiment according to the present invention. FIG. 2 is a plain view showing the solar cell module 100 in FIG. 1 which is seen from a rear surface side (lower side in FIG. 1). FIG. 3 is a sectional side view showing a portion of the solar cell module 100 in FIG. 1 and showing one desirable embodiment of an output wiring 104 (wiring). FIG. 4 is a sectional side view showing another desirable embodiment of an output wiring 104 in FIG. 1. In FIG. 2, for example, three solar cell elements 103 are shown, and in FIG. 1, diagrams of these solar cell elements 103 are simplified and are integrally shown. FIG. 3 is a diagram showing the left half portion of these solar cell elements 103. In FIG. 2, a transparent substrate 101, solar cell elements 103, and output wiring 104 are shown, and in FIG. 3, diagrams of a back sheet 102 and a terminal box 106 are omitted.

For example, the solar cell module 100 is equipped with a transparent glass substrate 101 (cover member) and a flexible back sheet 102 (cover member), and a space 100A is formed by the glass substrate 101 and the back sheet 102. Plural (for example, three) solar cell elements 103 are disposed in the space 100A. The solar cell elements 103 are electrically connected to internal wiring (not shown), and the output wiring 104 (wiring) is electrically connected to corner portions of the solar cell elements 103 on both end portion sides.

The output wiring 104 is disposed on rear surfaces of the solar cell elements 103, and is ejected from a hole portion 102A, which is formed at nearly center portion, to an external portion. When the output wiring 104 is long between the hole portion 102A and the solar cell element 103, it is difficult that water intruding from the hole portion 102A arrive to a surface (electric generation surface) of the solar cell element 103, so that durability of the solar cell elements 103 can be improved.

For example, as shown in FIG. 4, the output wiring 104 has a covering wiring having a conductor 111 and PET 112 (polyethylene terephthalate) which covers the conductor 111, and an adsorbent 113 absorbing water is provided on a surface of the covering wiring. The adsorbent 113 has a horizontal direction thickness w (width) parallel to a surface direction of the surface (electric generation surface) of the solar cell element, and a vertical direction thickness t perpendicular to the surface direction of the surface of the solar cell element 103, and it is desirable that the horizontal direction thickness w be thicker than the vertical direction thickness t. In order to prevent expansion of the rear surface, which may occur after being used outdoors, it is desirable that the vertical direction thickness t be 0.5 mm or less.

It is desirable that the adsorbent 113 be a film adhered to the surface of the covering wiring. A physical adsorption type composed of synthetic zeolite and the like or a chemical adsorption type composed of calcium oxide and the like is used as the film of the adsorbent 113. In this case, in comparison with the physical adsorption type, the chemical adsorption type is larger in absorption mount of moisture, and does not become transparent after absorbing water, so that the chemical adsorption type is desirably used. When the adsorbent 113 is composed of a material (silica gel or the like) absorbing and desorbing water, the water absorbed by the adsorbent 113 can be desorbed by heat, pressure, or the like, and this material is thereby desirable.

As shown in FIGS. 2 and 3, it is necessary that the adsorbent 113 be provided at least at the solar cell element 103 which is disposed at a central portion corresponding to a hole portion of the back sheet 102, and at the covering wire which is disposed at both end portions proximate to the solar cell element 103 at the central portion. In this feature, when plural solar cell elements 103 are disposed, intrusion of water can be prevented at a portion between the solar cell elements 103, at which the following protective resin communicates. Thus, this feature is desirable. In this case, since it is difficult that the protective resin 105 enter to a portion which is directly below the output wiring 104 on the rear surface of the solar cell element 103, as shown in FIG. 3, it is desirable that the adsorbent 113 (shown by diagonal line) be provided at least at the above portion directly below the output wiring 104.

The space 104A is sealed by the protective resin 105 composed of EVA (ethylene-vinyl acetate) or the like which protects the solar cell elements 103. A terminal box 106 (terminal portion) is provided at a portion at which the hole portion 102A is formed on an external surface of the back sheet 102. The terminal box 106 has a main body portion 106A and a cap portion 106B closing an opening portion of the main body portion 106A, and the output wiring 104 is ejected from a hole portion, which is formed at a side portion of the main body portion 106A, to the external portion. The internal portion of the terminal box 106 is sealed by a seal material 107 of silicon material (for example, silicone rubber).

In this embodiment, even when water arrive at the hole portion 102A of the back sheet 102 through a gap between the back sheet 102 and the terminal portion 106, through a gap between the cap portion 106B and the main body portion 106A of the terminal portion 106, and the like, since the adsorbent 113 absorbing water is provided on the surface of the output wiring 104 ejected to the external portion via the hole portion 102A of the back sheet 102, the water arriving at the hole portion 102A of the back sheet 102 is absorbed by the adsorbent 113 provided on the surface of the output wiring 104. Therefore, even when a gap is formed between the output wiring 104 and surrounding members on the rear surface side of the solar cell module 100, intrusion of water from the hole portion 102 A of the back sheet 102 through the output wiring 104 can be prevented. As a result, deterioration of reliability due to short circuit can be prevented. Since this effect can be obtained in a simple structure that the adsorbent 113 is provided on the surface of the output wiring 104, improvement of mass production, reduction of the number of parts, and reduction of production cost can be realized.

In particular, in the adsorbent 113 of the output wiring 104, the horizontal direction thickness w, which is parallel to the surface direction of the solar cell element 103, is thicker than the vertical direction thickness t, which is perpendicular to the surface direction of the solar cell element 103, so that the amount of water absorbed by the adsorbent 113 can be larger without making the thickness of the output wiring 104 thicker, and various problems of gas bubble and the like can be thereby prevented.

For example, the film including a material that absorbs and desorbs water is used as the adsorbent 113 of the output wiring 104, so that the water absorbed in the surface of the output wiring 104 can be desorbed by heat, pressure, or the like. Therefore, the durability of the solar cell module 100 can be improved.

What is claimed is:

1. A solar cell module comprising:
a solar cell element;
a wiring which is connected to the solar cell element;
a cover member which is disposed around the solar cell element;
a protective resin which seals a space between the solar cell element and the cover member;
a hole portion which is formed to the cover member, the wiring being ejected to an external portion via the hole portion;
a terminal portion which is provided at an external portion of the cover member, the wiring being connected to the terminal portion; and
an adsorbent which is provided on a surface of the wiring and absorbs water.

2. A solar cell module according to claim 1, wherein the adsorbent of the wiring has a horizontal direction thickness parallel to a surface direction of the solar cell element, and has a vertical direction thickness perpendicular to the surface direction of the solar cell element, and the horizontal direction thickness is thicker than the vertical direction thickness.

3. A solar cell module according to claim 1, wherein the adsorbent of the wiring is a film including a material that absorbs and desorbs water, and adheres to the surface of the wiring.

4. A solar cell module according to claim 1, wherein the terminal portion is sealed by a silicon material.
